(19) United States
(12) Patent Application Publication
(10) Pub. No.: US 2026/0065971 A1
(43) Pub. Date: Mar. 5, 2026

(54) CONTENTION MEASURES FOR MEMORY PACKAGES WITH BUFFER DIE

(71) Applicant: Micron Technology, Inc., Boise, ID (US)

(72) Inventors: Matthew A. Prather, Boise, ID (US); Randall J. Rooney, Boise, ID (US); Anthony D. Veches, Boise, ID (US); Navid Lashkarian, Pleasanton, CA (US); Sujeet Ayyapureddi, Boise, ID (US)

(73) Assignee: Micron Technology, Inc., Boise, ID (US)

(21) Appl. No.: 19/291,282

(22) Filed: Aug. 5, 2025

Related U.S. Application Data
(60) Provisional application No. 63/689,068, filed on Aug. 30, 2024.

(51) Int. Cl. G11C 11/4093; G11C 11/4076; G11C 11/4096

(52) U.S. Cl. CPC G11C 11/4093; G11C 11/4076; G11C 11/4096

(57) ABSTRACT

A memory package may include multiple memory devices and a buffer die in some examples. The buffer die may include a contention circuit that detects conflicts/contentions between commands from a controller and housekeeping operations of the memory. In some examples, the contention circuit may request the controller resend the command in the event of a contention. In some examples, the buffer die may further include a queue to store commands and/or data. The queue may store the commands/data and/or responses from the memory devices for a set period of time and/or until the contention circuit determines the contention no longer exists.

### CROSS REFERENCE TO RELATED APPLICATION(S)

This application claims the benefit under 35 U.S.C. § 119 of the earlier filing date of U.S. Provisional Application No. 63/689,068 filed Aug. 30, 2024, the entire contents of which is hereby incorporated by reference in its entirety for any purpose.

### BACKGROUND

This disclosure relates generally to semiconductor devices, and more specifically to semiconductor memory devices. In particular, the disclosure relates to memory, such as dynamic random access memory (DRAM). Information may be stored in memory cells, which may be organized into rows (word lines) and columns (bit lines) of an array. Various types of information may be stored in the array, such as data, error correction code (ECC) data, and metadata. The data may be information provided by an external device (e.g., controller, processor, host system). The ECC data may provide information that may be used to detect and/or correct errors in the data. The metadata may provide information about the data, ECC data, the memory device, and/or a device in communication with the memory device (e.g., a controller).

Semiconductor memory devices may store information in multiple memory cells. The information may be stored as a binary code, and each memory cell may store a single bit of information as either a logical high (e.g., a “1”) or a logical low (e.g., a “0”). The memory cells may be organized at the intersection of word lines (rows) and bit lines (columns) an array. The memory may further be organized into one or more memory banks. The banks may be organized into bank groups, where each bank group includes one or more banks. Each bank may include multiple of rows and columns. During operations, the memory device may receive a command and an address which specifies one or more rows and one or more columns and then execute the command on the memory cells at the intersection of the specified rows and columns (and/or along an entire row/column). The address may further specify the bank group and/or bank for execution of the command. In some applications, rows may be specified by 17-bit row addresses and columns may be specified by 12-bit column addresses. However, the number of bits used for the addresses may vary depending on the size and/or organization of the memory.

The columns may generally be organized into column planes, each of which includes a number of sets of individual columns all activated by a column select signal (CS) (e.g., column selects). Each bank may include some number X column planes. A column plane may receive some number N of column select (CS) signals, each of which may activate some number M of individual bit lines. As used herein, a column select set or CS set may generally refer to a set of bit lines which are activated by a given value of the CS signal within a column plane. The column select signal may be represented by (all or a portion of) a column address (CA). Responsive to a column select signal, data may be provided from corresponding locations from the column planes. The data from the column planes associated with the column select signal may be referred to as a cache line.

In many applications, multiple memory devices are used by a device and/or computing system. The memory devices may be packaged together in a memory module. For example, single in-line memory modules (SIMMs), dual in-line memory modules (DIMMS), small outline DIMMs (SODIMMs), and rambus in-line memory modules (RIMM) may include multiple memory devices.

FIG. 1A is a block diagram of at least a portion of a computing system. The computing system 10 includes a memory module 12 and a controller 16 in communication with the memory module 12. The memory module 12 may include module logic and buffers 18 and one or more memory devices 14.

The controller 16 may provide commands, addresses (CA), clock signals (CLK), and/or to one or more of the memory devices 14 and receive data from one or more of the memory devices 14. As shown, some or all of the signals transmitted between the controller 16 and memory devices 14 must pass through the module logic and buffers 18. The module logic and buffers 18 may facilitate coordination between the memory devices 14 (e.g., distributing clock signals). However, module logic and buffers 18 may also lead to “middleman” inefficiencies. Further, the module logic and buffers 18 are typically manufactured by an entity different from the entities that manufactured the memory devices 14 and controller 16. This may lead to quality control issues and/or unforeseen compatibility issues.

### BRIEF DESCRIPTION OF THE DRAWINGS

FIG. 1A is a block diagram of at least a portion of a computing system.

FIG. 1B is a block diagram of at least a portion of a computing system according to some embodiments of the present disclosure.

FIG. 2A is a diagram showing a multi-die device according to an embodiment of the disclosure.

FIG. 2B is a diagram showing a multi-die device according to an embodiment of the disclosure.

FIG. 2C is a block diagram of a memory device according to some embodiments of the present disclosure.

FIG. 3 is a functional block diagram of a buffer die according to at least one embodiment of the disclosure.

FIG. 4 is a flow chart of a method according to at least one embodiment of the disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced.

These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory package may include a stack of memory devices and at least one buffer die. The buffer die may include components that facilitate communication with a controller and/or host system. In some embodiments, the buffer die may include components that facilitate communication between memory packages. The memory packages may be included on a memory module. The memory packages disclosed herein may reduce or eliminate the need for additional devices on memory modules (e.g., buffers, logic). This may reduce reliability and/or compatibility issues in some applications. In some applications, it may provide faster communication between the memory package and the controller and/or host system.

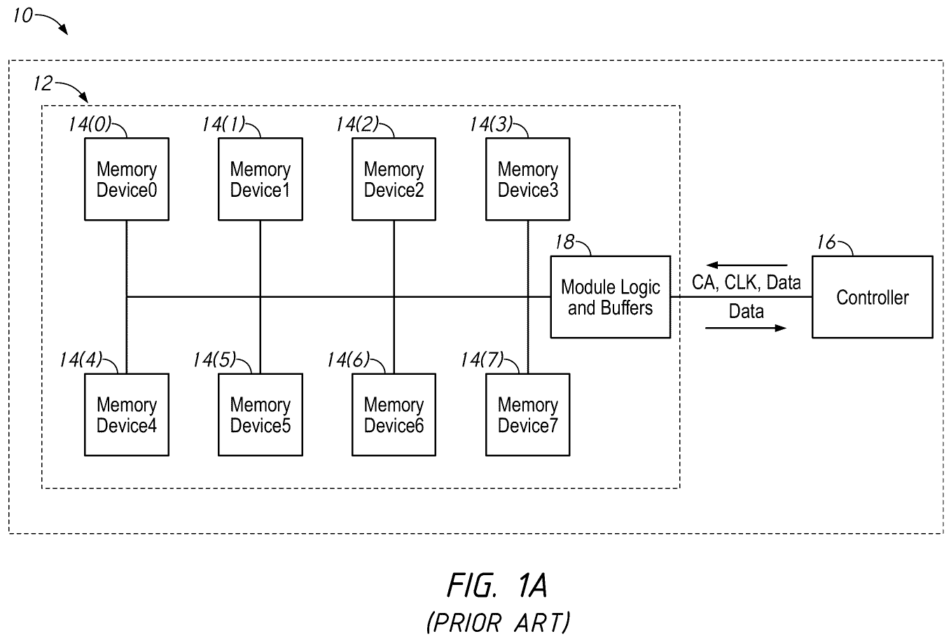

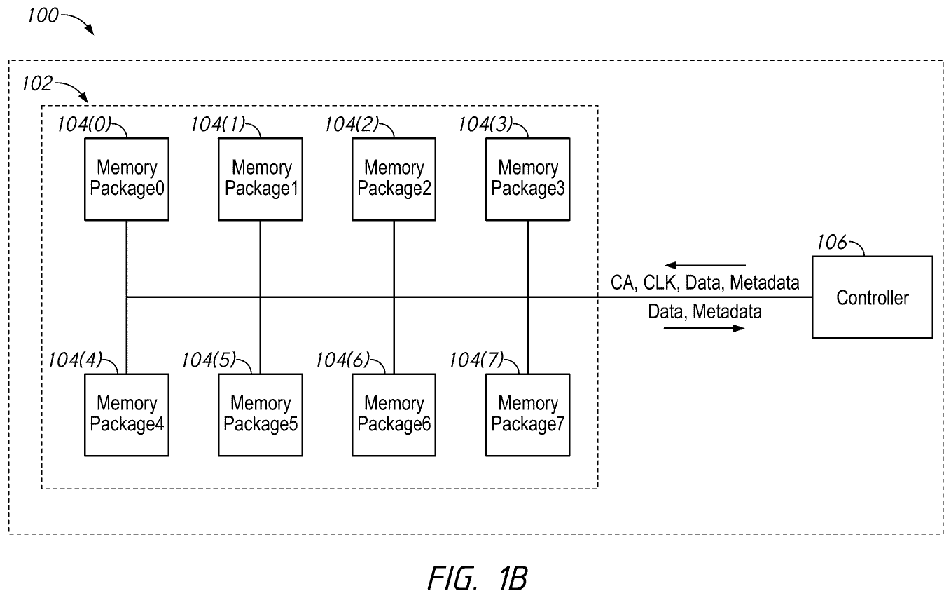

FIG. 1B is a block diagram of at least a portion of a computing system according to some embodiments of the present disclosure. The computing system 100 includes a memory module 102 and a controller 106 in communication with the memory module 102. In some embodiments, the controller 106 may be included in a processor (not shown) or in communication with the processor. The memory module 102 may include one or more memory packages 104. According to embodiments of the present disclosure, each memory package 104 may one or more memory devices and a buffer die. The memory devices may be stacked on the buffer die in some examples. In the example shown in FIG. 1, there are eight memory packages 104(0-7). However, in other embodiments, there may be more or fewer memory packages (e.g., 1 device, 2, devices, 4 devices, 16 devices). In some embodiments, additional memory packages 104 may be included to provide for redundancy. In some embodiments, memory module 102 may be a dual in-line memory module (DIMM). In some embodiments, what is shown in FIG. 1 may represent only half of the DIMM (e.g., one of the two channels). In other words, memory module 102 may include sixteen memory packages 104.

The controller 106 may provide signals such as commands, addresses, clock signals and/or data (e.g., data, metadata, or both) to one or more of the memory packages104 and receive signals such as data from one or more of the memory packages 104. According to embodiments of the present disclosure, the controller 106 may provide and receive signals from the memory die via the buffer die. In some embodiments, memory package 104 may be x16 or x32 memory devices. That is, either 16 or 32 DQ terminals (e.g., pins) may be active. In some embodiments, the memory package 104 may support both x16 and x32 operation. In some embodiments, whether the memory package 104 operate in x4 or x8 mode may be based, at least in part, on values stored in mode registers (not shown in FIG. 1) of the memory packages 104. In some embodiments, the memory packages 104 may be x4, x8, or x64 memory packages.

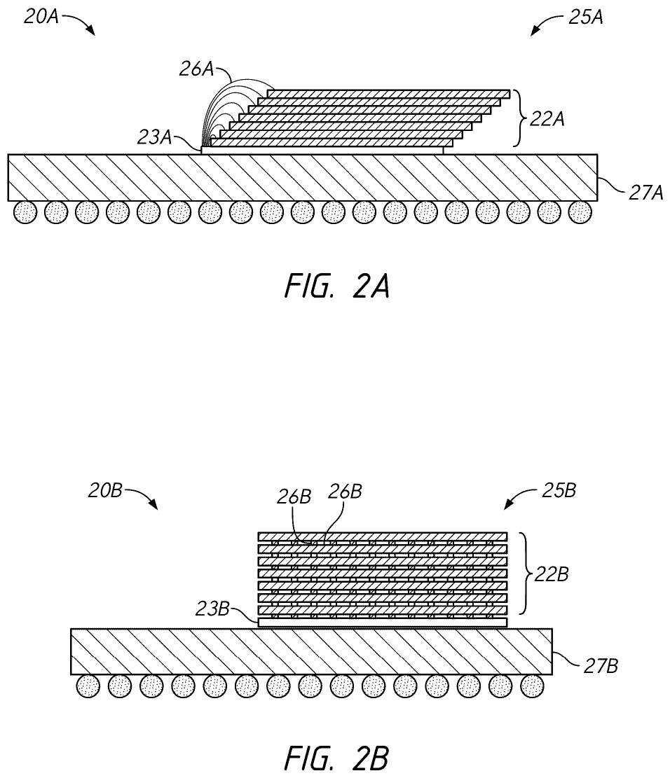

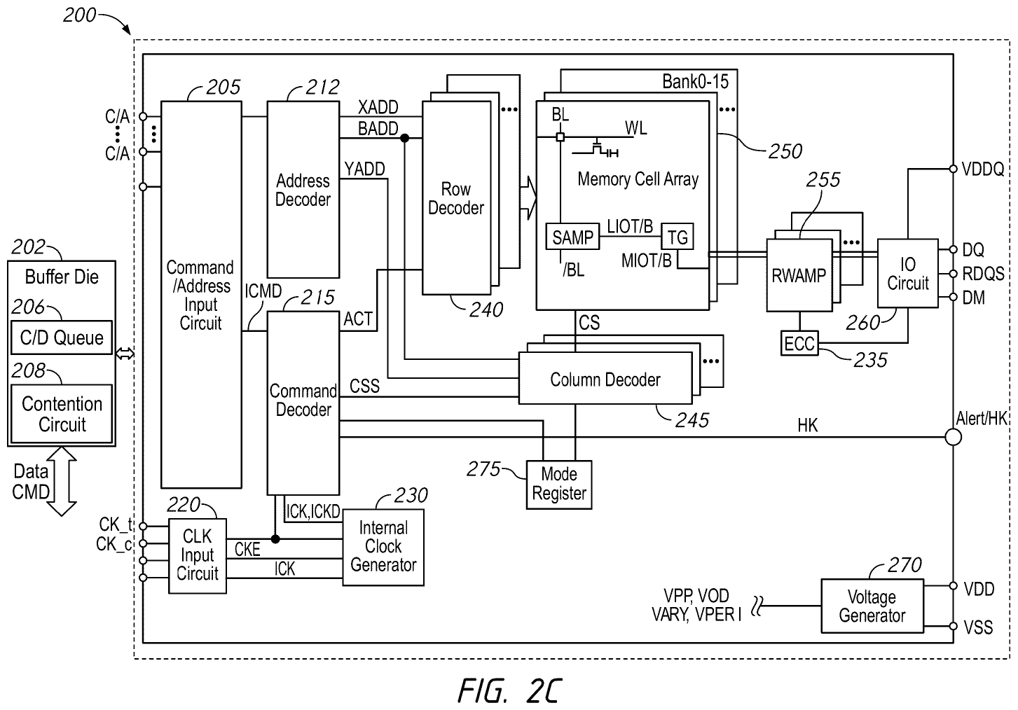

FIG. 2A is a diagram showing a multi-die device according to an embodiment of the disclosure. The multi-die device 20A may include a stack 25A of memory devices 22A (e.g., memory die) and a buffer die 23A. Embodiments of the disclosure are not limited to the particular number of memory devices 22A included in the stack 25A shown in FIG. 2A. For example, the stack 25A may include 1-16 memory devices 22A. Further, while one buffer die 23A is shown in FIG. 2A, in some embodiments, there may be two buffer die 23A per stack 25A. In some embodiments of the disclosure, the stack 25A may be included in one or more of memory packages 104.

The memory devices 22A and buffer die 23A may be stacked in a staggered manner, providing a “shingle-stack” configuration for the stack 25A as shown in FIG. 2A. However, the memory devices 22A and buffer die 23A may be stacked in other configuration such as a staggered configuration. The memory devices 22A and/or buffer die 23A may be attached to one another. In some embodiments of the disclosure, the semiconductor devices 22A are attached to one another by an adhesive epoxy.

The memory devices 22A and/or buffer die 23A may include a pad formation area, a peripheral circuit area, and memory cell array areas (not shown in FIG. 2A) that include memory cells, circuits, and signal lines, for example, sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 22A and/or buffer die 23A.

The pad formation area may include a plurality of bond pads disposed along the edge of the memory devices 22A and/or buffer die 23A. The plurality of bond pads may be coupled to the terminals of the semiconductor device and represent external terminals of the memory devices 22A and/or buffer die 23A. For example, the plurality of bond pads may include data terminals, command and address terminals, clock terminals, and/or power supply terminals.

Circuits included in the memory cell array area and/or circuits of the peripheral circuit area may be coupled to one or more bond pads included in the pad formation area. Various circuits of the memory devices 22A and/or buffer die 23A may be coupled to the terminals. Conductive structures may be used to couple the terminals to one or more of the bond pads. As a result, the circuits coupled to the terminals are also coupled to the bond pads. The conductive structures may extend from locations of the terminals included in the memory cell array area and/or the peripheral circuit area to the pad formation area.

The memory devices 22A may be offset from one another to allow edge regions of the memory devices 22A to be exposed. The exposed edge regions may include the bond pads to which conductors 26A may be coupled. In some embodiments of the disclosure, the bond pads of the edge regions may be conductive pads. The bond pads may be coupled to terminals of the respective memory device 22A. In some embodiments of the disclosure, the conductors 26A are bond wires. While the conductors 26A in FIG. 2A are shown coupling all of the memory devices 22A to the buffer die 23A, the conductors 26A may be coupled in other configurations. For example, the conductors 26A may couple adjacent memory devices 22A to one another, and the lowest memory device 22A may be coupled to the buffer die 23A by the conductors 26A in a “daisy chain” configuration.

The stack 25A may be attached to a substrate 27A. The stack 25A may be attached to the substrate 27A by an adhesive epoxy in some embodiments of the disclosure. The substrate 27A may include conductive signal lines to route signals along the substrate, for example, to and from the memory devices 22A and/or buffer die 23A. Other circuits may also be attached to the substrate 27A and coupled to the conductive signals lines as well. As a result, the circuits attached to the substrate 27A may be coupled, for example, to the memory devices 22A and/or buffer die 23A through the conductive signal lines of the substrate 27A and conductors coupled to the conductive signal lines and the bond pads of the memory devices 22A and/or buffer die 23A. In some embodiments, the substrate 27A may be included in memory module 102.

FIG. 2B is a diagram showing a multi-die device according to an embodiment of the disclosure. The multi-die device 20B may include a stack 25B of memory devices 22B and a buffer die 23B. Embodiments of the disclosure are not limited to the particular number of memory devices 22B included in the stack 25B shown in FIG. 2B. For example, the stack 25B may include 1-16 memory devices 22B. Further, while one buffer die 23B is shown in FIG. 2B, in some embodiments, there may be two buffer die 23B per stack 25B. In some embodiments of the disclosure, the stack 25B may be included in one or more of the memory packages 104.

The memory devices 22B and/or buffer die 23B may include a pad formation area, a peripheral circuit area, and memory cell array areas (not shown in FIG. 2B) that include memory cells, circuits, and signal lines, for example, sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 22B and/or buffer die 23B.

The memory devices 22B and buffer die 23B may be stacked in an aligned manner, such that the edges of the memory devices 22B are substantially aligned. When the buffer die 23B is a similar dimension to the memory devices 22B, the buffer die 23B may be substantially aligned with the memory devices 22B as well as shown in FIG. 2B. However, the memory devices 22B and buffer die 23B may be stacked in other configuration such as a staggered configuration.

In contrast to stack 25A, the memory devices 22B and/or buffer die 23B are electrically coupled to one another by through silicon vias (TSVs) 26B rather than being coupled by conductors 26A. In some embodiments, instead of or in addition to pad formation areas, the memory devices 22B and/or buffer die 23B may include TSV formation areas. The memory devices 22B and/or buffer die 23B may be physically attached to one another by additional mechanisms (e.g., not just the TSVs). In some embodiments of the disclosure, the semiconductor devices 22B are attached to one another by an adhesive epoxy.

The stack 25B may be attached to a substrate 27B. The stack 25B may be attached to the substrate 27B by an adhesive epoxy in some embodiments of the disclosure. The substrate 27B may include conductive signal lines to route signals along the substrate, for example, to and from the memory devices 22B and/or buffer die 23B. Other circuits may also be attached to the substrate 27B and coupled to the conductive signals lines as well. As a result, the circuits attached to the substrate 27B may be coupled, for example, to the memory devices 22B and/or buffer die 23B through the conductive signal lines of the substrate 27B and conductors coupled to the conductive signal lines and the bond pads of the memory devices 22B and/or buffer die 23B. In some embodiments, the substrate 27B may be included in memory module 102.

In some embodiments, the buffer die 23A, 23B is a memory device substantially similar to memory devices 22A, 22B. In some embodiments, memory devices 22A, 22B may have certain logic circuits disabled and/or bypassed, and the buffer die 23A, 23B has such logic circuits enabled and acts as a “target” or “master” die. In some embodiments, the buffer die 23A, 23B is a different device with different components than the memory devices 22A, 22B.

As described in more detail herein, the buffer die 23A, 23B may include components for handling contention between a host and/or controller (e.g., controller 106) and the memory devices 22A, 22B. In between executing commands from the controller, the memory devices 22A, 22B may perform various internal operations such as auto-refresh operations to maintain data integrity. The memory devices 22A, 22B may perform additional refresh operations (e.g., targeted refresh operations) to combat memory attacks such as row hammers. These are merely two examples, and additional or different internal operations may be performed by the memory devices 22A, 22B. These internal operations are sometimes referred to as “housekeeping.”

Typically, memory devices are deterministic. That means that a controller may provide a command at a certain time and expect a result (e.g., ability to transmit or receive data) at a set time interval after providing the command. Thus, a memory device must be able to execute the command within the set time interval in order to provide the expected result. For example, properly receive data from the controller or for the controller to properly receive data from the memory device.

In the past, when there was contention between a housekeeping operation and a command from the controller, the command would take precedence over the housekeeping. As memory devices get denser, the amount of required housekeeping is also increasing. The contention between housekeeping and commands may also increase. Furthermore, to protect the data and/or security of the memory devices 22A, 22B, it may not always be feasible to give precedence to the command from the controller. That is, the memory devices 22A, 22B may need to prioritize a housekeeping operation over a command from the controller in some instances.

According to embodiments of the present disclosure, a buffer die (e.g., buffer die 23A, 23B) of a memory package may include a contention circuit for detecting contentions between commands from a controller and housekeeping operations of one or more memory devices (e.g., memory devices 22A, 22B) of the memory package. In some embodiments, the buffer die may include a queue to store commands and/or data associated with the commands. The contention circuit may permit certain housekeeping activities to continue even when a command is received from a controller. In some embodiments, the contention circuit may queue commands and/or data when a contention is detected and allow the commands and/or data to be passed to the memory device(s) when the contention is no longer present. Storing commands and/or data in a queue rather than passing the commands and/or data between the controller and the memory devices may be referred to as queuing or buffering.

In some embodiments, the contention circuit may queue commands and/or data regardless of a contention, which may provide a buffer for the memory devices to perform housekeeping activities. While this embodiment may increase latency of the memory package, it may allow the memory package to act in a deterministic manner. In some embodiments, the contention circuit may provide a signal to the controller to resend the command and/or data when a contention is detected and/or the queue is full. Requesting the controller to resend the command when the contention is detected, regardless of queue status, may allow the memory package to act in a deterministic manner.

The memory packages according to the present disclosure may allow memory devices to perform additional housekeeping activities while allowing commands from the controller to be executed in a dynamic or deterministic interactions with the controller.

FIG. 2C is a block diagram of a memory device according to some embodiments of the present disclosure. The apparatus may be a semiconductor device. In some embodiments, the memory device 200 may include, without limitation, a dynamic random access (DRAM) device integrated into a single semiconductor chip. In some examples, the DRAM may be a double data rate (DDR) memory device. In some embodiments, it may be a DDR5 or DDR6 memory device. In some embodiments, one or all of the memory devices 22A, 22B of FIGS. 2A and 2B may include memory device 200.

The memory device 200 includes a memory array 250. The memory array 250 includes a plurality of banks BANK0-15, each bank including a plurality of word lines WL, a plurality of bit lines BL, and a plurality of memory cells MC arranged at intersections of the plurality of word lines WL and the plurality of bit lines BL. Although sixteen banks are shown in FIG. 2, memory array 250 may include any number of banks. The selection of the word line WL is performed by a row decoder 240 and the selection of the bit line BL is performed by a column decoder 245. Sense amplifiers (SAMP) are located for their corresponding bit lines BL and connected to at least one respective local I/O line pair (LIOT/B), which is in turn coupled to at least respective one main I/O line pair (MIOT/B), via transfer gates (TG), which function as switches. The TG may be coupled to one or more read/write amplifiers (RWAMP) 255, which may be coupled to an error correction code (ECC) circuit 235. The ECC circuit 235 may be coupled to an IO circuit 260, which may be coupled to one or more external terminals of semiconductor device 200. Read data from the bit line BL is amplified by the sense amplifier SAMP, and transferred to read/write amplifiers 255 over complementary local data lines (LIOT/B), transfer gate (TG), and complementary main data lines (MIOT/B) to the ECC circuit 235. Conversely, write data outputted from the ECC circuit 235 is transferred to the sense amplifier SAMP over the complementary main data lines MIOT/B, the transfer gate TG, and the complementary local data lines LIOT/B, and written in the memory cell MC coupled to the bit line BL.

The memory device 200 may employ a plurality of external terminals that include command and address terminals coupled to a command/address (C/A) bus to receive command and address signals, clock terminals to receive clock signals CK_t and CK_c, data terminals DQ, RDQS, and power supply terminals VDD, VSS, VDDQ, and VSSQ.

The C/A terminals may be supplied with an address and a bank address signal from outside, for example, from a buffer die 202. Buffer die 202 may be buffer die 23A and/or buffer die 23B in some embodiments. The address signal and the bank address signal supplied to the address terminals are transferred, via a command/address input circuit 205, to an address decoder 212. The address decoder 212 receives the address signals and supplies a decoded row address signal XADD to the row decoder 240, and a decoded column address signal YADD to the column decoder 245. The address decoder 212 also receives the bank address signal BADD and supplies the bank address signal to the row decoder 240 and the column decoder 245.

The C/A terminals may further be supplied with command signals from, for example, buffer die 202. In some embodiments, buffer die 202 may receive commands and addresses from a controller, such as controller 106. The command signals may be provided as internal command signals ICMD to a command decoder 215 via the command/address input circuit 205. The command decoder 215 includes circuits to decode the internal command signals ICMD to generate various internal signals and commands for performing operations, for example, a row activation signal (ACT) to select a word line. Another example may be providing internal signals to enable circuits for performing operations, such as control signals to enable signal input buffers that receive clock signals.

Each bank BANK0-15 may be organized into multiple physical column planes (CP). Each column plane may be associated with multiple column selects (e.g., CS0-63, CS0-59, CS0-55). In some embodiments, different column planes may be used to store different types of information. For example, some column planes may store data and another plane stores ECC data. Optionally, a further plane may store global column redundancy (GCR) data. Optionally, the array 250 can store metadata in one or more column planes. In some embodiments, a column plane may store more than one type of information (e.g., data and metadata, metadata and ECC data)

The C/A terminals may receive an access command which is a read command. When a read command is received, and a bank address, a row address and a column address are timely supplied with the read command, a codeword including read data, metadata, and read ECC data (e.g., parity bits) is read from memory cells in the memory array 250 corresponding to the row address and column address. The read command is received by the command decoder 215, which provides internal commands so that read data from the memory array 250 is provided to the ECC circuit 235. The ECC circuit 235 may use the parity bits in the codeword to determine if the codeword includes any errors, and if any errors are detected, may correct them to generate a corrected codeword (e.g., by changing a state of the identified bit(s) which are in error). The corrected codeword (without the parity bits) is output from the data terminals DQ via the input/output circuit 260.

The C/A terminals may receive an access command which is a write command. When the write command is received, and a bank address, a row address, and a column address are timely supplied as part of the write operation, and write data is supplied through the DQ terminals to the ECC circuit 235. The write data (which may include write data and metadata) supplied to the data terminals DQ is written to a memory cells in the memory array 250 corresponding to the row address and column address. The write command is received by the command decoder 215, which provides internal commands so that the write data is received by data receivers in the input/output circuit 260. The write data is supplied via the input/output circuit 260 to the ECC circuit 235. The ECC circuit 235may generate ECC data (e.g., a number of parity bits) based on the write data, and the write data and the parity bits may be provided as a codeword to the memory array 250 to be written into the memory cells MC.

The command decoder 215 may access mode register 275 that is programmed with information for setting various modes and features of operation for the semiconductor device 200. For example, the mode register 275 may provide parameters that allow the semiconductor device 200 to operate at different frequencies, provide different burst lengths, allow banks BANK0-15 to be organized into different groups, operate in x8 or x16 mode, and/or other different operating conditions. In some embodiments, mode register 275 may include multiple registers.

The information in the mode register 275 may be programmed by providing the memory device 200 a mode register write command, which causes the memory device 200 to perform a mode register write operation. In some embodiments, data to be written to the mode register 275 is provided via the C/A terminals and/or the DQ terminals. The command decoder 215 accesses the mode register 275, and based on the programmed information along with the internal command signals provides the internal signals to control the circuits of the memory device 200 accordingly. Information programmed in the mode register 275 may be externally provided by the memory device 200 using a mode register read command, which causes the memory device 200 to access the mode register 275 and provide the programmed information (e.g., to the buffer die 202). In some embodiments, the information may be provided via the C/A terminals and/or the DQ terminals.

Turning to the explanation of the external terminals included in the memory device 200, the clock terminals and data clock terminals are supplied with external clock signals and complementary external clock signals. The external clock signals CK_t, CK_c may be supplied to a clock input circuit 220. When enabled, input buffers included in the clock input circuit 220 pass the external clock signals. For example, an input buffer passes the CK_t and CK_c signals when enabled by a CKE signal from the command decoder 215. The clock input circuit 220 may use the external clock signals passed by the enabled input buffers to generate internal clock signal ICK. The internal clock signal ICK are supplied to internal clock circuit 230 for providing one or more clock signals to the various components of memory device 200.

The internal clock circuits 230 includes circuits that provide various phase and frequency controlled internal clock signals based on the received internal clock signals. For example, the internal clock circuits 230 may include a clock path (not shown in FIG. 2) that receives the ICK clock signal and provides internal clock signals ICK and ICKD to the command decoder 215. Optionally, the input/output circuit 260 may include clock circuits and driver circuits for generating and providing the RDQS signal to a controller.

The power supply terminals are supplied with power supply potentials VDD and VSS. These power supply potentials VDD and VSS are supplied to an internal voltage generator circuit 270. The internal voltage generator circuit 270 generates various internal potentials VPP, VOD, VARY, VPERI. The internal potential VPP is mainly used in the row decoder 240, the internal potentials VOD and VARY are mainly used in the sense amplifiers included in the memory array 250, and the internal potential VPERI is used in many other circuit blocks.

The power supply terminal is also supplied with power supply potential VDDQ. The power supply potentials VDDQ is supplied to the input/output circuit 260 together with the power supply potential VSS. The power supply potential VDDQ may be the same potential as the power supply potential VDD in an embodiment of the disclosure. The power supply potential VDDQ may be a different potential from the power supply potential VDD in another embodiment of the disclosure. However, the dedicated power supply potential VDDQ is used for the input/output circuit 260 so that power supply noise generated by the input/output circuit 260 does not propagate to the other circuit blocks.

According to embodiments of the present disclosure, the memory device 200 may perform housekeeping activities such as auto-refreshes, targeted refreshes, and/or other internal functions. When the memory device 200 is unable to perform commands received from the buffer die 202 due to the housekeeping activities, the memory device 200 may provide a housekeeping signal HK (e.g., provide an active signal, activate the HK signal) to the buffer die 202. The HK signal may be provided on a pre-existing multi-use terminal (e.g., Alert pin) or a dedicated HK signal terminal. In other embodiments, the HK signal may be provided on a different terminal, such as one of the C/A terminals. When the memory device 200 is capable of performing commands (e.g., finished housekeeping activities), the memory device 200 may stop providing the HK signal (e.g., provide an inactive signal, deactivate the HK signal).

The buffer die 202 may include a contention circuit 208 in some embodiments. The contention circuit 208 may receive the HK signal from the memory device 200. As described the buffer die 202 may receive data and commands from an external device, such as a controller and/or host system (not shown in FIG. 2C). The contention circuit 208 may determine when there is a conflict (e.g., contention) between the command and the housekeeping activities of the memory device 200. By conflict or contention, it is meant that the command, if provided to the memory device 200, may not be completed by the memory device 200 in a time “expected” by the external device due to the performance of housekeeping activities by the memory device 200. The expected time may be defined by a specification of the memory device 200 and/or a standard (e.g., JEDEC DDR standard).

In some embodiments, the buffer die 202 may include a command and data (C/D) queue 206. The C/D queue 206 may store commands received from the external device. The C/D queue 206 may store data associated with the received commands in some embodiments. The C/D queue 206 may be implemented by any suitable non-transitory storage medium (e.g., latches, registers, memory array). In some embodiments, all commands and data received from the external device may be provided to the C/D queue 206. In some embodiments, the C/D queue 206 may store commands and/or data when the contention circuit 208 determines a contention exists.

As disclosed herein, the contention circuit 208 and C/D queue 206 may control when commands are provided to the memory device 200 for execution to allow the memory device 200 to complete housekeeping activities. This may improve data integrity and/or security of the memory device 200 in some applications.

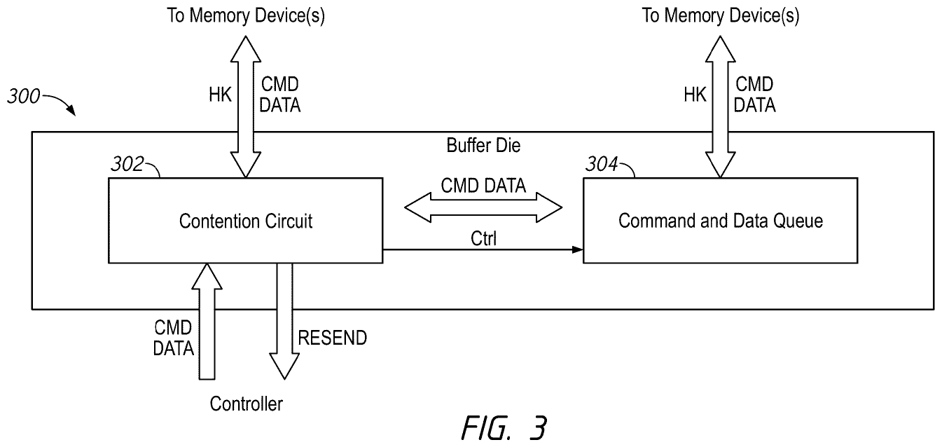

FIG. 3 is a functional block diagram of a buffer die according to at least one embodiment of the disclosure. Buffer die 300 may be included buffer die 202, buffer die 23A, and/or buffer die 23B. Buffer die 300 may include a contention circuit 302 and command and data (C/D) queue 304. Although, in some embodiments, the C/D queue 304 may only store commands. In some embodiments, the contention circuit 302 may be included in contention circuit 208, and C/D queue 304 may be included in C/D queue 206. FIG. 3 is a functional block diagram, and the arrangement of the components is to illustrate the passing of information between components and is not meant to reflect the physical arrangement of the components.

The contention circuit 302 of buffer die 300 may receive commands from a controller (e.g., controller 106). The controller may be in communication with or included in a host system in some embodiments. The contention circuit 302 may also receive housekeeping (HK) signals from the memory devices (e.g., memory devices 22A, 22B, 200). An active HK signal may indicate that a memory device is performing one or more housekeeping operations. The contention circuit 302 may determine if there is contention (e.g., conflict) between the command from the controller and the housekeeping operation. For example, the contention circuit 302 may determine there is contention when a command is received for a memory device when the HK signal from the memory device is active. The contention circuit 302 may determine there is no contention when a command is received when the HK signal from the memory device is inactive.

In some embodiments, regardless of whether a contention is detected, the command may buffered in the C/D queue 304. Optionally, if data is associated with the command, the data may also be stored in the C/D queue 304. In some embodiments, the command (and data) are provided to the memory device from the C/D queue 304 after a set period of time. In some embodiments, the contention circuit 302 may control when a command is provided to the memory, and a response from the memory device (e.g., data, status signal) may be provided to the C/D queue 304. If the response is provide prior to the set time period, the C/D queue 304 may buffer the response until the set period of time. After the set period of time, the response may be provided to the controller from the buffer die 300. The set period of time may be defined by a specification of the memory package and/or a standard. By delaying providing commands to the memory and/or responses to the controller, this embodiment allows the memory to continue in a deterministic manner. However, this increases latency for all commands, even when extra time is not needed for housekeeping operations.

In some embodiments, when a contention is detected, the contention circuit 302 may send a resend signal (RESEND) requesting the controller to resend the command (and associated data if applicable). When no contention is detected, the contention circuit 302 allows the command (and associated data if applicable) to pass to the appropriate memory device(s). This may allow commands to be executed without added latency when it is not necessary, and delaying execution of commands when housekeeping is required. Further, commands that are executed may be executed in a deterministic manner. However, the controller must be capable of receiving and complying with RESEND signals. In these embodiments, the controller must be capable of operating when one or more commands must be resent to the memory package.

In some embodiments, when no contention is detected, the contention circuit 302 allows the command (and associated data if applicable) to pass to the appropriate memory device(s) as in the previous embodiment. When a contention is detected, the command and associated data are provided to the C/D queue 304. When the contention is resolved (e.g., the HK signal is inactive), the contention circuit 302 may cause the command and data to be provided from the command and data queue 304 to the appropriate memory device(s) for execution. This embodiment also avoids adding latency to commands that do not have a contention. However, it causes the memory package to act in a non-deterministic manner. Thus, the controller must be capable of commands being executed at variable times. In some embodiments, additional signals or bits may be used as handshakes between the memory package and the controller to indicate what commands are completed when. For example, a signal or additional bits may be provided to indicate what command is associated with read data output by the memory package.

In some embodiments, the contention circuit 302 may include multiple contention circuits, for example, one for each memory device in the memory package. In some embodiments, the C/D queue 304 may include multiple queues, for example, one for each memory device in the memory package. Further, while FIG. 3 shows the contention circuit 302 providing data and commands to the C/D queue 304, in some embodiments, a commands and/or data may be provided directly between the controller and the C/D queue 304. The contention circuit 302 may receive the command and provide control signals (Ctrl) to the C/D queue 304 to cause commands and/or data to be stored and/or provided to the memory device(s) and/or controller.

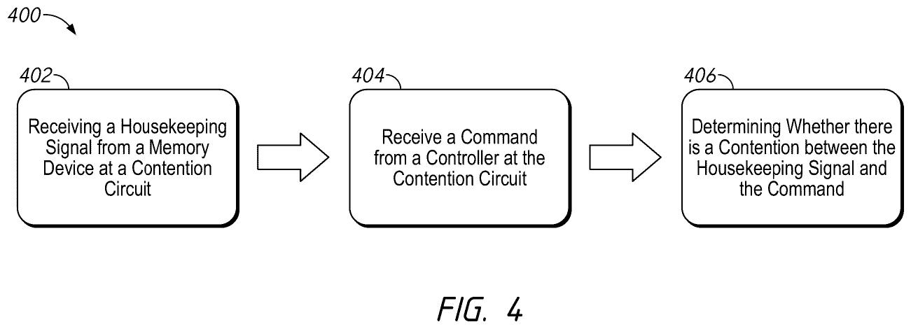

FIG. 4 is a flow chart of a method according to at least one embodiment of the disclosure. The method shown in flowchart 400 may be performed in whole or in part by a buffer die of a memory package, for example, buffer die 300, buffer die 202, buffer die 23A, and/or buffer die 23B.

At block 402, “receiving a housekeeping signal from a memory device at a contention circuit” may be performed. In some embodiments, the signal may be received from an external terminal of the memory device, such as an alert pin or a dedicated housekeeping signal pin. At block 404, “receiving a command from a controller at the contention circuit” may be performed. In some embodiments, data associated with the command may also be received.

At block 406, “determining whether there is a contention between the housekeeping signal and the command” may be performed. In some embodiments, the contention exists when the housekeeping signal is in a first state and the contention does not exist when the housekeeping signal is in a second state. By “exists” it means the contention circuit has made a determination that the contention exists based on the command and housekeeping signal state.

In some embodiments, the method shown in flowchart 400 may further include providing the command to the memory device when the housekeeping signal is in the second state.

In some embodiments, the method shown in flowchart 400 may further include providing the command to a queue of the buffer die. In some examples, the command is provided to the queue when the contention exists. In some examples, the method further includes providing data associated with the command to the queue.

In some embodiments, the method shown in flowchart 400 may further include providing the command from the queue to the memory device. In some examples, the command is provided from the queue after a set period of time (e.g., when the memory package operates in a deterministic manner). In some examples, the command is provided from the queue when the contention does not exist (e.g., when the memory package operates in a dynamic manner).

In some embodiments, the method shown in flowchart 400 may further include receiving a response from the memory device and storing the response in the queue. In some examples, the method further includes providing the response from the queue to the controller after a set period of time, such as when the memory package is operating in a deterministic manner.

In some embodiments, the queue is controlled by the contention circuit. In these embodiments, the method shown in flowchart 400 may further include providing control signals from the contention circuit to a queue to cause the queue to store the command, provide the command to the memory device, or a combination thereof.

In some embodiments, the method shown in flowchart 400 may further include a resend signal from the contention circuit to the controller when the contention exists. In these embodiments, the controller may resend the command responsive to the resend signal.

The systems, methods, and apparatuses disclosed herein may allow memory devices to perform additional housekeeping activities while allowing commands from the controller to be executed in a dynamic or deterministic interactions with the controller.

Of course, it is to be appreciated that any one of the examples, embodiments or processes described herein may be combined with one or more other examples, embodiments and/or processes or be separated and/or performed amongst separate devices or device portions in accordance with the present systems, devices and methods. For example, a buffer die may have all or some of the features of the buffer dice disclosed in the present application.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory device; and
a buffer die in communication with the memory device, the buffer die configured to receive a housekeeping signal from the memory device and a command from a controller, wherein the buffer die is configured to determine whether a contention between the housekeeping signal and the command exists.

2. The apparatus of claim 1, wherein the comprises an external terminal configured to provide the housekeeping signal.

3. The apparatus of claim 2, wherein the external terminal comprises an alert pin.

4. The apparatus of claim 1, wherein the buffer die comprises a contention circuit configured to determine the contention exists when the housekeeping signal is in a first state when the command is received and the contention does not exist when the housekeeping signal is in a second state when the command is received.

5. The apparatus of claim 1, wherein the buffer die comprises a queue configured to store the command, data, or a combination thereof.

6. The apparatus of claim 5, wherein the queue comprises a non-transitory storage medium.

7. The apparatus of claim 5, wherein the buffer die comprises a contention circuit configured to determine whether the contention exists and the queue is configured to receive the command, the data, or the combination thereof from the contention circuit.

8. The apparatus of claim 1, further comprising a plurality of memory devices, wherein the memory device is included in the plurality of memory devices, wherein the buffer is configured to receive a plurality of housekeeping signals from the plurality of memory devices and determine whether the contention between the plurality of housekeeping signals and the command exists.

9. A method comprising:
receiving a housekeeping signal from a memory device at a contention circuit of a buffer die;
receiving a command from a controller at the contention circuit; and
determining whether there is a contention between the housekeeping signal and the command, wherein:
the contention exists when the housekeeping signal is in a first state, and
the contention does not exist when the housekeeping signal is in a second state.

10. The method of claim 9, further comprising providing the command to the memory device when the housekeeping signal is in the second state.

11. The method of claim 9, further comprising providing the command to a queue of the buffer die.

12. The method of claim 11, wherein the command is provided to the queue when the contention exists.

13. The method of claim 11, further comprising providing data associated with the command to the queue.

14. The method of claim 11, further comprising providing the command from the queue to the memory device.

15. The method of claim 14, wherein the command is provided from the queue after a set period of time.

16. The method of claim 14, wherein the command is provided from the queue when the contention does not exist.

17. The method of claim 14, further comprising:
receiving a response from the memory device; and
storing the response in the queue.

18. The method of claim 17, further comprising providing the response from the queue to the controller after a set period of time.

19. The method of claim 9, further comprising providing a resend signal from the contention circuit to the controller when the contention exists.

20. The method of claim 9, further comprising providing control signals from the contention circuit to a queue to cause the queue to store the command, provide the command to the memory device, or a combination thereof.
